(19) United States
(12) Patent Application Publication
(10) Pub. No.: US 2019/0215997 A1
(43) Pub. Date: Jul. 11, 2019

(54) OPTICAL COMPONENT MOUNTING DEVICE AND METHOD FOR MANUFACTURING SENSOR DEVICE

(71) Applicant: SHARP KABUSHIKI KAISHA, Sakai City, Osaka (JP)

(72) Inventors: SHOHGO HIROOKA, Sakai City (JP); YOSHIHITO ISHIZUE, Sakai City (JP); HIDEYUKI KURIMOTO, Sakai City (JP)

(21) Appl. No.: 16/331,257

(22) PCT Filed: May 17, 2017
(86) PCT No.: PCT/JP2017/018564

§ 371 Date: Mar. 7, 2019

(30) Foreign Application Priority Data
Sep. 8, 2016 (JP) 2016-175760

(51) Int. Cl. H05K 13/04; H05K 1/02

(52) U.S. Cl. CPC H05K 13/0409; H05K 1/02

(57) ABSTRACT

Manufacturing of a high-resolution sensor device is enabled. An optical component mounting device (100) includes a pressing portion (3), which presses an optical component from a side on which a suction portion (1) is disposed after the suction portion (1) stops sucking.

### TECHNICAL FIELD

The present invention relates to an optical component mounting device and a method for manufacturing a sensor device.

### BACKGROUND ART

High-density mounting has been progressing these days in mounting of a camera module (sensor device), and a flexible printed circuit (hereinafter also referred to as an FPC) is often used as a member on which the camera module is mounted. An FPC usually includes a variable portion and a fixed portion, and a camera module is often mounted on the fixed portion.

If the fixed portion on which a camera module is mounted is warped, a sensor included in the camera module may be accordingly warped, and may have its image surface bent and its image capturing degraded. Thus, preventing warpage of the fixed portion of an FPC on which a camera module is mounted is important.

As an example of a technology for preventing warpage of an FPC, PTL 1 discloses a technology for preventing warpage of an FPC by equalizing the coefficient of thermal expansion of one main surface with that of the other main surface of the ETC. In addition, PTL 2 discloses a technology for further preventing warpage by forming substantially the same patterns on both surfaces of a substrate.

Meanwhile, resolution improvement of a camera module has been rapidly progressing. The resolution improvement poses a big challenge of improving component precision: a precise adjustment in height between an image-surface facing lens (optical component) and a sensor is required in an assembly process.

Moreover, a camera module mounted on a mobile terminal is required to reduce its profile. Thus, the profile reduction and the size reduction of components of a camera module have been progressing. To achieve profile reduction, an image-surface facing lens is disposed immediately above the sensor in some camera modules. In the case where an image-surface facing lens is disposed immediately above the sensor, the image-surface facing lens is often fixed to the substrate.

### CITATION LIST

### Patent Literature

PTL 1: Japanese Unexamined Patent Application Publication “No. 2013-105810 (disclosed on May 30, 2013)”

PTL 2: Japanese Unexamined Patent Application Publication. “No. 2009-158748 (disclosed on Jul. 16, 2009)”

### SUMMARY OF INVENTION

### Technical Problem

When the image-surface facing lens is to be fixed to the substrate, the image-surface facing lens is bonded to the substrate with, for example, an adhesive. Here, the image-surface facing lens is fixed to the substrate while being slightly unstably disposed on the substrate due to a pressure from the adhesive. Thus, the image-surface facing lens is more likely to tilt with respect to the light receiving portion of the sensor, and this tilt causes a problem of lowering the resolution of the camera module.

The present invention is made to address this problem, and aims to provide an optical component mounting device and a sensor device manufacturing method that enable manufacturing of a high-resolution sensor device.

### Solution to Problem

To solve the above problem, an optical component mounting device according to an aspect of the present invention includes a suction portion that sucks an optical component, which guides light to a sensor mounted on a substrate; a hold-mount portion that holds the optical component sucked by the suction portion, and mounts the optical component on either one or both of the substrate and the sensor; and a pressing portion that presses the optical component from a side on which the suction portion is disposed after the suction portion stops sucking the pressing portion.

To solve the above problem, a method for manufacturing a sensor device according to an aspect of the present invention includes a step of sucking an optical component that guides light to a sensor mounted on a substrate; a step of holding the sucked optical component and mounting the optical component on either one or both of the substrate and the sensor; a step of stopping sucking; and a step of pressing the optical component from a side from which the optical component is sucked after sucking is stopped.

To solve the above problem, a method for manufacturing a sensor device according to an aspect of the present invention includes a step of mounting an optical component, which guides light to a sensor mounted on a substrate, on either one or both of the substrate and the sensor; and a step of pressing the optical component from a side opposite to a side on which the substrate and the sensor are disposed.

### Advantageous Effects of Invention

According to an aspect of the present invention, a method for manufacturing a high-resolution sensor device is achieved.

### BRIEF DESCRIPTION OF DRAWINGS

FIGS. 1(a) to 1(f) illustrate the structure of an optical component mounting device according to a first embodiment of the present invention in the state where a suction portion is not sucking.

FIGS. 2(a) to 2(f) illustrate the structure of the optical component mounting device according to the first embodiment of the present invention in the state where a suction portion is sucking.

FIG. 3 illustrates a method for manufacturing a sensor device according to the first embodiment of the present invention, and includes first cross sections of the optical component mounting device illustrated in FIG. 1(a).

FIG. 4 illustrates the method for manufacturing a sensor device according to the first embodiment of the present invention, and includes second cross sections of the optical component mounting device illustrated in FIG. 1(a).

FIG. 5(a) illustrates a method for manufacturing a sensor device according to a second embodiment of the present invention, and FIG. 5(b) illustrates a method for manufacturing a sensor device according to a third embodiment of the present invention.

### DESCRIPTION OF EMBODIMENTS

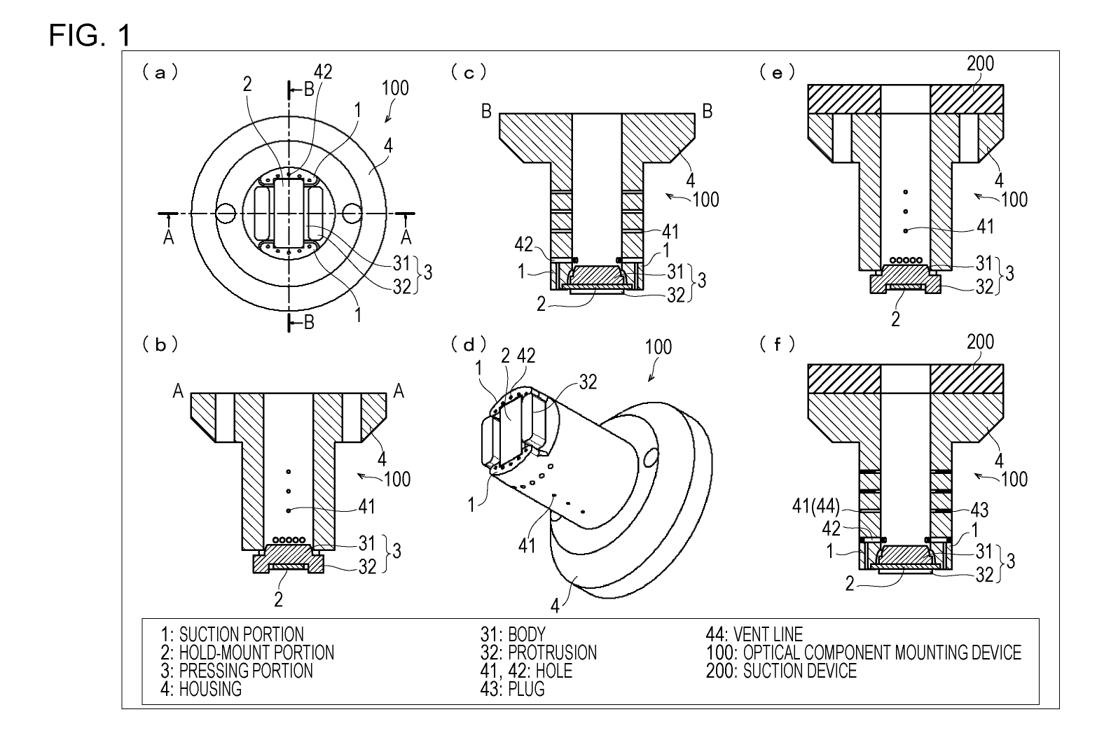

Embodiments of the present invention will now be described with reference to FIG. 1 to FIG. 4.

### First Embodiment

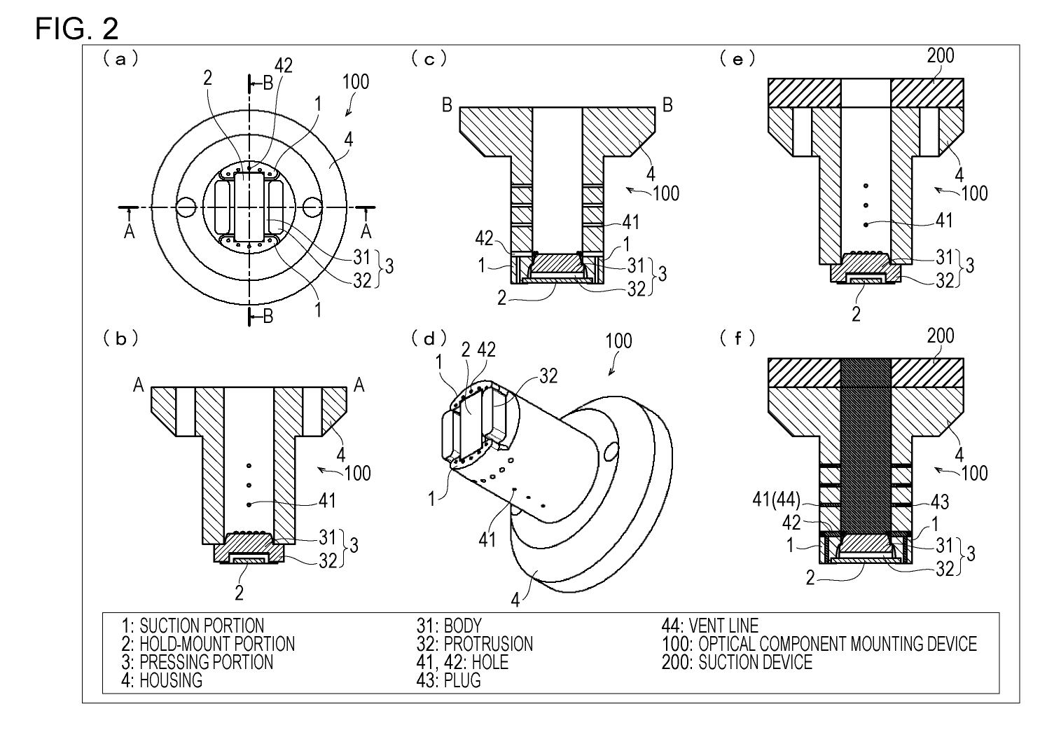

FIG. 1(a) to FIG. 1(f) illustrate the structure of an optical component mounting device 100 according to a first embodiment of the present invention in the state where a suction portion 1 is not sucking. FIG. 2(a) to FIG. 2(f) illustrate the structure of the optical component mounting device 100 according to the first embodiment of the present invention in the state where the suction portion 1 is sucking.

Specifically, FIG. 1(a) and FIG. 2(a) are bottom views of the optical component mounting device 100. FIG. 1(b) and FIG. 2(b) are first cross-sectional views (cross-sectional views taken along line A-A and viewed in the arrow direction) of the optical component mounting device 100 illustrated in FIG. 1(a) and FIG. 2(a). FIG. 1(c) and FIG. 2(c) are second cross-sectional views (cross-sectional views taken along line B-B and viewed in the arrow direction) of the optical component mounting device 100 illustrated in FIG. 1(a) and FIG. 2(a). FIG. 1(d) and FIG. 2(d) are perspective views of the optical component mounting device 100. FIG. 1(e) and FIG. 1(f) and FIG. 2(e) and FIG. 2(f) illustrate the optical component mounting device 100 in the state of being fixed to a suction device 200. FIG. 1(e) and FIG. 2(e) illustrate first cross sections of the optical component mounting device 100 illustrated in FIG. 1(a) and FIG. 2(a). FIG. 1(f) and FIG. 2(f) illustrate second cross sections of the component mounting device 100 illustrated in FIG. 1(a) and FIG. 2(a).

The optical component mounting device 100 includes a suction portion 1, a hold-mount portion 2, a pressing portion 3, and a housing 4.

The housing 4 is a cylindrical member having openings at both ends. The suction device 200 is attached to a first end of the housing 4. The suction device 200 sucks air in the space defined by the housing 4. The housing 4 has six holes 41, which extend linearly through the side wall of the housing 4, and ten holes 42, which extend through the housing 4 from the side wall of the housing 4 to a second end of the housing 4.

The suction portion 1 sucks an optical component that guides light to a sensor mounted on a substrate. The suction portion 1 corresponds to the second end of the housing 4. The ten holes 42 are formed at the suction portion 1. When the suction device 200 sucks the pressing portion 3, the suction portion 1 can suck an object near the ten holes 42 using the ten holes 42.

The hold-mount portion 2 holds an optical component sucked by the suction portion 1 to mount the optical component on either one or both of a substrate and a sensor. The hold-mount portion 2 is disposed to partially cover an opening at the second end of the housing 4, and fixed to the suction portion 1. Particularly, in the optical component mounting device 100, the suction portion 1 includes two segments in the bottom view of the optical component mounting device 100. The hold-mount portion 2 is fixed to the suction portion 1 to extend between the two segments.

The pressing portion 3 presses an optical component from the side closer to the suction portion 1 after the suction portion 1 stops sucking the pressing portion 3. The pressing portion 3 is not fixed to a specific member, but has its movement restricted by the hold-mount portion 2.

The pressing portion 3 includes a body 31 and protrusions 32, protruding from the body 31. The operations of the body 31 and the protrusions 32 will now be described. The operations of the body 31 and the protrusions 32 described below are operations performed while the optical component mounting device 100 is in an erect state, that is, in the state where the second end of the housing 4 faces immediately downward.

The body 31 is disposed closer to the first end of the housing 4 than the hold-mount portion 2. In the state where the suction portion 1 (refer to FIG. 1(a) to FIG. 1(f)) is not sucking, the body 31 is disposed on the hold-mount portion 2. Specifically, the hold-mount portion 2 has a function of receiving (holding) the pressing portion 3 to prevent the pressing portion 3 from falling in the state where the suction portion 1 is not sucking. On the other hand, in the state where the suction portion 1 is sucking (refer to FIG. 2(a) to FIG. 2(f)), the body 31 is spaced above the hold-mount portion 2.

The protrusions 32 are disposed at portions at which they do not overlap the hold-mount portion 2 in the bottom view of the optical component mounting device 100. In the state where the suction portion 1 is not sucking, far ends of the protrusions 32 are located below the hold-mount portion 2. On the other hand, in the state where the suction portion 1 is sucking, the far ends of the protrusions 32 are located above the hold-mount portion 2 with the body 31 being spaced above the hold-mount portion 2.

As illustrated in FIG. 1(f) and FIG. 2(f), five of the six holes 41 are blocked with plugs 43 in the optical component mounting device 100 attached to the suction device 200. Here, the hole 41 not blocked with the plugs 43 functions as a vent line 44. The vent line 44 is a path for releasing the space defined by the housing 4 to the atmosphere immediately after the suction device 200 stops sucking.

The number of the holes 41 may be smaller than or equal to five, or greater than or equal to seven. The number of holes 42 may be smaller than or equal to nine, or greater than or equal to eleven. The number of the vent lines 44 may be greater than or equal to two. An excessively large number of the vent lines 44, however, weakens the suction force of the suction portion 1. Thus, an excessive increase of the number of the vent lines 44 is not preferable. In addition, the holes 41 or the holes 42 having an excessively large diameter weaken the suction force of the suction portion 1. Thus, the diameter of the hole 41 and holes 42 is preferably smaller than or equal to 0.3 mm.

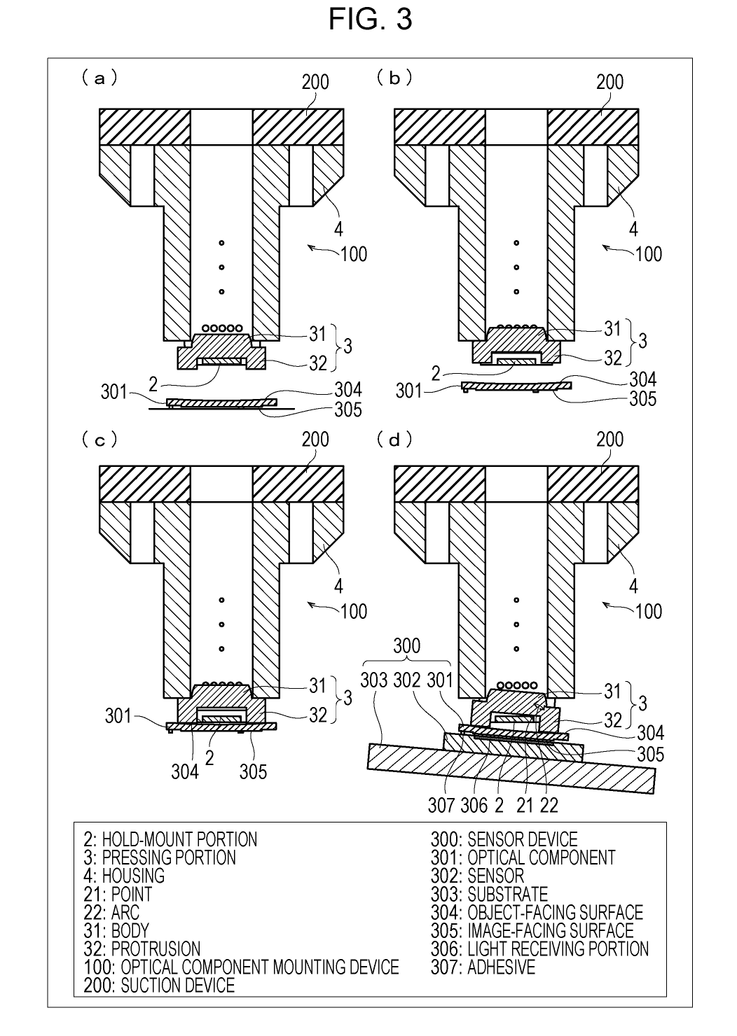

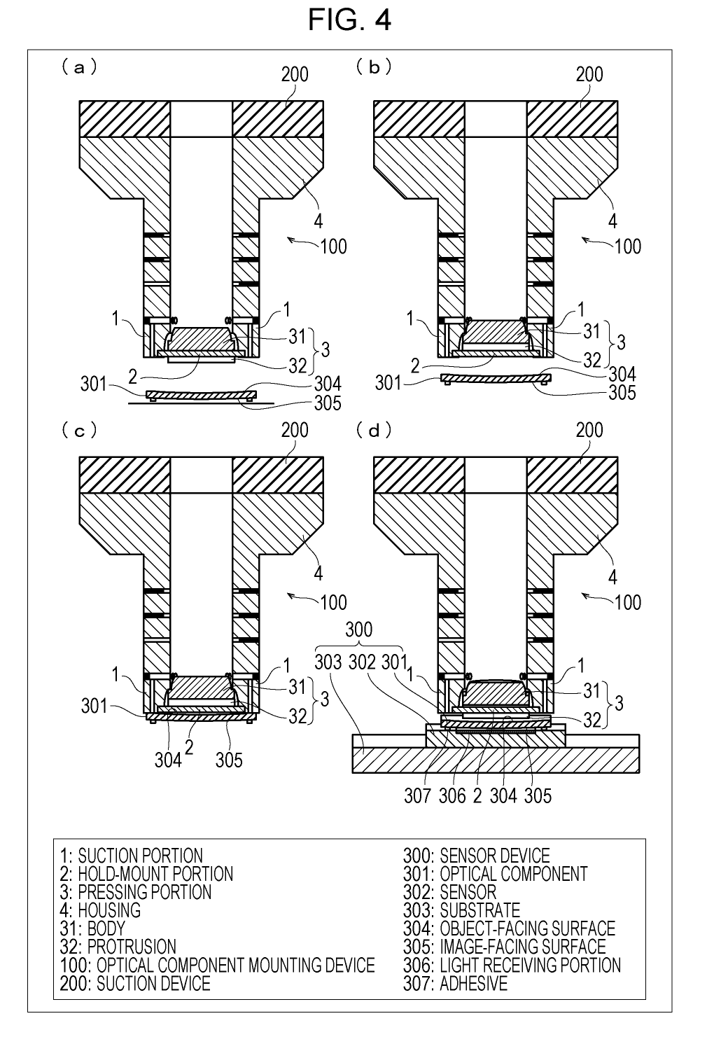

A method for manufacturing a sensor device 300 including an optical component 301 and a sensor 302 will now be described with reference to FIG. 3 and FIG. 4. FIG. 3 and FIG. 4 illustrate a method for manufacturing the sensor device 300 according to the first embodiment of the present invention. FIG. 3(a) to FIG. 3(d) illustrate first cross sections of the optical component 301 illustrated in FIG. 1(a). FIG. 4(a) to FIG. 4(d) illustrate second cross sections of the optical component 301 illustrated in FIG. 1(a).

FIG. 3(a) to FIG. 3(d) and FIG. 4(a) to FIG. 4(d) illustrate a method for manufacturing a sensor device 300 using the optical component mounting device 100. The steps described below are steps performed while the optical component mounting device 100 is in the erect state, that is in the state where the second end of the housing 4 faces immediately below.

FIG. 3(a) and FIG. 4(a) illustrate the state where the suction portion 1 is not sucking (refer to FIG. 1(a) to FIG. 1(f)). Here, as described above, the far ends of the protrusions 32 of the pressing portion 3 are located below the hold-mount portion 2.

FIG. 3(b) and FIG. 4(b) illustrate the state where the suction portion 1 starts sucking. Here, the suction portion 1 sucks the optical component 301. As described with reference to FIG. 2(a) to FIG. 2(f), the body 31 of the pressing portion 3 is spaced above the hold-mount portion 2, and thus the far ends of the protrusions 32 are located above the hold-mount portion 2.

In the present embodiment, the optical component 301 is a so-called lens on chip (LOC) lens, and has an object-facing surface 304, facing an object in the state of being installed in the sensor device 300, and an image-facing surface 305, facing an image surface in the same state.

FIG. 3(c) and FIG. 4(c) illustrate a step of holding the optical component 301 with the hold-mount portion 2. Here, the far ends of the protrusions 32 are located above the hold-mount portion 2. Thus, the hold-mount portion 2 can hold the sucked optical component 301 by coming into contact with the object-facing surface 304.

FIG. 3(d) and FIG. 4(d) illustrate a step of mounting the optical component 301 held by the hold-mount portion 2 on the sensor 302. The sensor 302 is mounted on a substrate 303, and includes a light receiving portion 306, which receives light at its surface opposite to the surface facing the substrate 303. The optical component 301 guides light to the light receiving portion 306 of the sensor 302. In this step, the suction portion 1 stops sucking. Thus, the optical component 301 falls from the hold-mount portion 2. Concurrently with the optical component 301 falling from the hold-mount portion 2, the body 31 falls and is received by the hold-mount portion 2, and the far ends of the protrusions 32 shift to positions below the hold-mount portion 2. With this shift, the far ends of the protrusions 32 press the optical component 301 from the suction portion 1.

The optical component 301 is mounted on the sensor 302 by bonding (attaching), with an adhesive 307, the image-facing surface 305 and the sensor 302 to each other. When the far ends of the protrusions 32 press the optical component 301 from the side closer to the suction portion 1, the optical component 301 is pressed against the sensor 302. Thus, the optical component 301 can be prevented from being fixed to the sensor 302 while being unstably disposed on the sensor 302 due to the pressure from the adhesive 307. Thus, the optical component 301 can be prevented from tilting with respect to the light receiving portion 306, so that the resolution of the sensor device 300 can be improved.

The pressing portion 3 has a weight such that the body 31 can be raised while being sucked by the suction portion 1 and such that the optical component 301 can be pressed against the sensor 302 against the pressure of the adhesive 307, and for example, approximately 0.5 g.

Preferably, the pressing portion 3 is rotatable about the hold-mount portion 2 while being received by the hold-mount portion 2. With a play being formed between the pressing portion 3 and the housing 4, the pressing portion 3 is made rotatable, for example, along an arc 22 about a point 21 in the hold-mount portion 2, as illustrated in FIG. 3(d). Since the pressing portion 3 is rotatable, the rotation of the pressing portion 3 can absorb tilt of the sensor 302 with respect to the optical component 301 held by the hold-mount portion 2. This structure can thus more securely prevent the optical component 301 from tilting with respect to the light receiving portion 306.

### Second Embodiment

In the first embodiment, the method for manufacturing the sensor device 300, which presses, after sucking is stopped, the optical component 301 from the side that is sucked, using the optical component mounting device 100 has been described. However, a method for manufacturing the sensor device 300, which presses the optical component 301 from the side opposite to the side on which the sensor 302 and the substrate 303 are disposed, without using the optical component mounting device 100 is also included in the scope of the present invention.

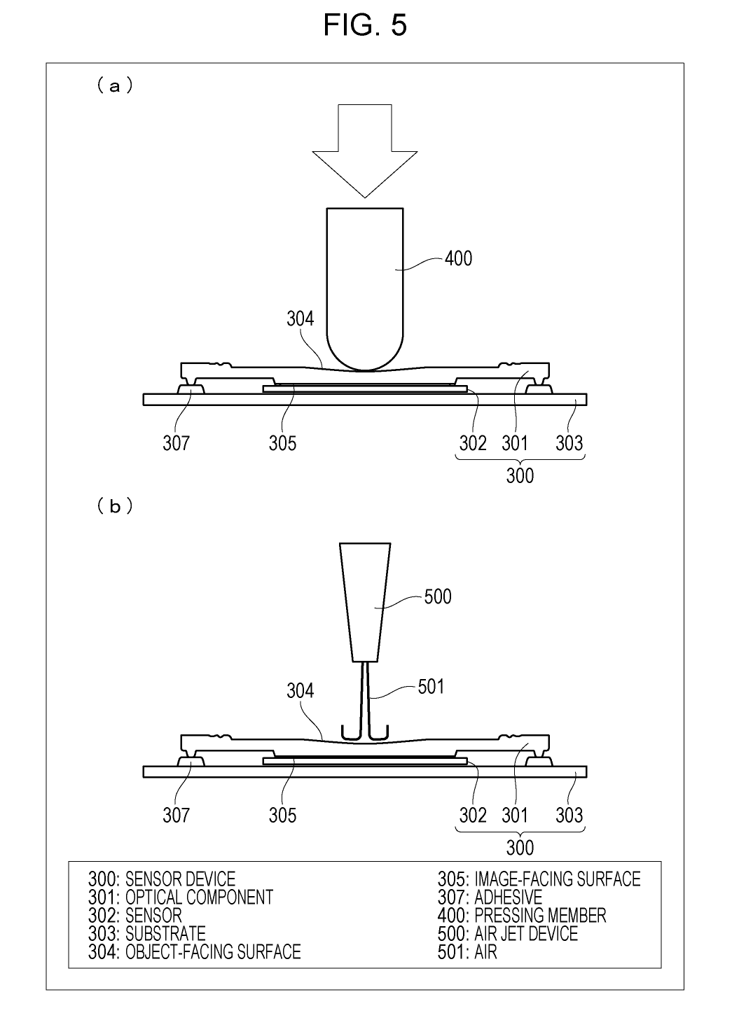

FIG. 5(a) illustrates a method for manufacturing a sensor device 300 according to a second embodiment of the present invention.

In the manufacturing method illustrated in FIG. 5(a), the optical component 301 is bonded to the substrate 303 with the adhesive 307, and then the optical component 301 is pressed from the side opposite to the side on which the substrate 303 and the sensor 302 are disposed (that is, from the object-facing surface 304). Then, the optical component 301 is pressed by a pressing member 400. The pressing member 400 may be formed from any object that hardly ever damages the object-facing surface 304 and that is made of a material that or has a shape that hardly ever makes the object-facing surface 304 dirty.

In the method for manufacturing the sensor device 300 illustrated in FIG. 3(a) to FIG. 3(d) and FIG. 4(a) to FIG. 4 (d), the optical component 301 is bonded to the sensor 302 with the adhesive 307. On the other hand, in the method for manufacturing the sensor device 300 illustrated in FIG. 5(a), the optical component 301 is bonded to the substrate 303 with the adhesive 307. In the method for manufacturing the sensor device 300 according to the present invention, the optical component 301 may be bonded to the sensor 302, the optical component 301 may be bonded to the substrate 303, or the optical component 301 may be bonded to both of the sensor 302 and the substrate 303.

### Third Embodiment

FIG. 5(b) illustrates a method for manufacturing a sensor device 300 according to a third embodiment of the present invention.

In the manufacturing method illustrated in FIG. 5(b) after the optical component 301 is bonded to the substrate 303 with the adhesive 307, the optical component 301 is pressed from the side opposite to the side on which the substrate 303 and the sensor 302 are disposed (that is, from the object-facing surface 304). Thereafter, the optical component 301 is pressed by air 501 ejected from an air jet device 500.

Also in the method for manufacturing the sensor device 300 illustrated in FIG. 5(b), the optical component 301 is bonded to the substrate 303 with the adhesive 307.

### Conclusion

An optical component mounting device according to a first aspect of the present invention includes a suction portion that sucks an optical component, which guides light to a sensor mounted on a substrate; a hold-mount portion that holds the optical component sucked by the suction portion, and mounts the optical component on either one or both of the substrate and the sensor; and a pressing portion that presses the optical component from a side on which the suction portion is disposed after the suction portion stops sucking.

In the above-described structure, when the pressing portion presses the optical component from the side on which the suction portion is disposed, the optical component is pressed against the sensor or the substrate. This structure can thus prevent the optical component from being fixed to the sensor or the substrate while being unstably disposed on the sensor or the substrate due to the pressure from the adhesive. Thus, the optical component can be prevented from tilting with respect to the light receiving portion of the sensor, and can thus improve the resolution of the sensor device.

In the optical component mounting device according to a second aspect of the present invention, in relation to the first aspect, the hold-mount portion holds the pressing portion while the suction portion is not sucking.

The above structure can prevent the pressing portion from falling while the suction portion is not sucking.

In an optical component mounting device according to a third aspect of the present invention, in relation to the second aspect, the pressing portion is rotatable about the hold-mount portion in a state of being held by the hold-mount portion.

In the above-described structure, since the pressing portion is rotatable, the rotation of the pressing portion can absorb tilt of the sensor or the substrate with respect to the optical component held by the hold-mount portion. This structure can thus more securely prevent the optical component from tilting with respect to the light receiving portion of the sensor.

A method for manufacturing a sensor device according to a fourth aspect of the present invention includes a step of sucking an optical component that guides light to a sensor mounted on a substrate; a step of holding the sucked optical component and mounting the optical component on either one or both of the substrate and the sensor; a step of stopping sucking; and a step of pressing the optical component from a side from which the optical component is sucked after sucking is stopped.

The above-described structure can improve the resolution of the sensor device with the principle the same as that of each of the above-described optical component mounting devices.

A method for manufacturing a sensor device according to a fifth aspect of the present invention includes a step of mounting an optical component, which guides light to a sensor mounted on a substrate, on either one or both of the substrate and the sensor; and a step of pressing the optical component from a side opposite to a side on which the substrate and the sensor are disposed.

The above-described structure can improve the solution of the sensor device by pressing an optical component mounted on either one or both of a substrate and a sensor from a side opposite to a side on which the substrate and the sensor are disposed without performing a step of sucking the optical component.

The present invention is not limited to the above-described embodiments, and may be changed in various different manners within the scope of claims. Embodiments formed by appropriately combining technical measures disclosed in different embodiments are also included in the technical scope of the present invention. New technical features can be formed by combining technical measures disclosed in the embodiments.

### REFERENCE SIGNS LIST

1 suction portion
2 hold-mount portion
3 pressing portion
4 housing
21 point
22 arc
31 body
32 protrusion
41, 42 hole
43 plug
44 vent line
100 optical component mounting device
200 suction device
300 sensor device
301 optical component
302 sensor
303 substrate
304 object-facing surface
305 image-facing surface
306 light receiving portion
307 adhesive
400 pressing member
500 air jet device
501 air

1. An optical component mounting device, comprising:
a suction portion that sucks an optical component, which guides light to a sensor mounted on a substrate;
a hold-mount portion that holds the optical component sucked by the suction portion, and mounts the optical component on either one or both of the substrate and the sensor; and
a pressing portion that presses the optical component from a side on which the suction portion is disposed after the suction portion stops sucking.

2. The optical component mounting device according to claim 1, wherein the hold-mount portion holds the pressing portion while the suction portion is not sucking.

3. The optical component mounting device according to claim 2, wherein the pressing portion is rotatable about the hold-mount portion in a state of being held by the hold-mount portion.

4. A method for manufacturing a sensor device, comprising:
a step of sucking an optical component that guides light to a sensor mounted on a substrate;
a step of holding the sucked optical component and mounting the optical component on either one or both of the substrate and the sensor;
a step of stopping sucking; and
a step of pressing the optical component from a side from which the optical component is sucked after sucking is stopped.

5. A method for manufacturing a sensor device, comprising:
a step of mounting an optical component, which guides light to a sensor mounted on a substrate, on either one or both of the substrate and the sensor; and
a step of pressing the optical component from a side opposite to a side on which the substrate and the sensor are disposed.
